(19) United States
(12) Patent Application Publication
(10) Pub. No.: US 2026/0271383 A1
(43) Pub. Date: Sep. 10, 2026

(54) NP RATIO TUNING TECHNIQUES FOR NANORIBBON-BASED TRANSISTOR WITH DOUBLE-HEIGHT CELL

(71) Applicants: Tao Chu, Portland, OR (US); Guowei Xu, Portland, OR (US); Lin Hu, Portland, OR (US); Feng Zhang, Portland, OR (US); Ting-Hsiang Hung, Beaverton, OR (US); Chia-Ching Lin, Portland, OR (US); Yang Zhang, Rio Rancho, NM (US); Kan Zhang, Hillsboro, OR (US); Chun Wing Yeung, Portland, OR (US); Michal Mleczko, Portland, OR (US); Qiwen Wang, Portland, OR (US); Jae Hur, Hillsboro, OR (US); Yanbin Luo, Portland, OR (US); Chung-Hsun Lin, Portland, OR (US); Tahir Ghani, Portland, OR (US)

(72) Inventors: Tao Chu, Portland, OR (US); Guowei Xu, Portland, OR (US); Lin Hu, Portland, OR (US); Feng Zhang, Portland, OR (US); Ting-Hsiang Hung, Beaverton, OR (US); Chia-Ching Lin, Portland, OR (US); Yang Zhang, Rio Rancho, NM (US); Kan Zhang, Hillsboro, OR (US); Chun Wing Yeung, Portland, OR (US); Michal Mleczko, Portland, OR (US); Qiwen Wang, Portland, OR (US); Jae Hur, Hillsboro, OR (US); Yanbin Luo, Portland, OR (US); Chung-Hsun Lin, Portland, OR (US); Tahir Ghani, Portland, OR (US)

(21) Appl. No.: 19/074,918

(22) Filed: Mar. 10, 2025

(51) Int. Cl. H10D 84/83; H10D 30/00; H10D 30/47; H10D 62/10; H10D 64/66

(52) U.S. Cl. CPC H10D 84/833; H10D 30/47; H10D 30/506; H10D 62/118; H10D 64/665

(57) ABSTRACT

Examples of integrated circuit (IC) structures with a merged nanoribbon-based transistor fabricated using NP ratio tuning techniques are described herein. In one example, an IC structure may include a different gate electrode material around a wider portion of the nanoribbon than around a narrower portion of the nanoribbon. In another example, a wider portion of a nanoribbon may have a smaller thickness than a narrower portion of the nanoribbon. In another example, a gate dielectric material may be thicker around a wider portion of the nanoribbon than around a narrower portion of the nanoribbon. One or more of these techniques may be used to adjust the strength of a nanoribbon (e.g., the P-type nanoribbon) to achieve a desired NP ratio with or without using a jog in the IC circuit design.

### BACKGROUND

For the past several decades, the scaling of features in integrated circuit (IC) structures has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize every portion of an IC structure becomes increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIG. 2 is a top-down plan view of an example of an IC structure including a double-height merged nanoribbon-based transistor with a jog, in accordance with any of the embodiments disclosed herein.

FIG. 3 illustrates a top-down plan view of an example of an IC structure 300 including a merged nanoribbon-based transistor without a jog, in accordance with any of the embodiments disclosed herein.

FIGS. 4A-4B, 5A-5B, 6A-6B, and 7A-7B illustrate example IC structures including a double-height merged nanoribbon-based transistor fabricated using NP ratio tuning techniques, in accordance to embodiments disclosed herein.

FIG. 8 is a top view of a wafer and dies that may include any of the IC structures disclosed herein, in accordance with any of the embodiments disclosed herein.

FIG. 9 is a side, cross-sectional view of an IC device that may include any of the IC structures disclosed herein, in accordance with any of the embodiments disclosed herein.

FIG. 10 is a side, cross-sectional view of an IC package that may include any of the IC structures disclosed herein, in accordance with various embodiments.

FIG. 11 is a side, cross-sectional view of an IC device assembly that may include any of the IC structures disclosed herein, in accordance with any of the embodiments disclosed herein.

FIG. 12 is a block diagram of an example electrical device that may include any of the IC structures disclosed herein, in accordance with any of the embodiments disclosed herein.

### DETAILED DESCRIPTION

Disclosed herein are integrated circuit (IC) structures including nanoribbon-based transistors fabricated using NP ratio tuning techniques, in accordance with examples described herein. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Integrated circuits may be designed using a library of cells. For example, a cell in such a library may define a pre-designed component or logic gate, such as an inverter, a flip-flop, or other component. Cells in a library may be designed to fit within defined physical and electrical standards so that the cells may be laid out in the desired locations to build the desired circuit. For example, cells may be “standard height” or “single height” cells with a pre-defined cell size (e.g., height and width), where the height may refer to a dimension of the cell along the y-axis in a top-down view, and the width may refer to a dimension of the cell along an x-axis in a top-down view. Other cells may be “double-height,” where a double-height cell has a larger height than the standard cell (e.g., twice the height).

As the cell dimensions are scaled down, the dimensions of the transistors in those cells are also shrinking. For example, as cell height shrinks, the nanoribbon width of nanoribbon-based transistors in a cell also shrink. In some cases, smaller nanoribbon widths can negatively impact device performance, such as in high-current driver circuits. Another challenge encountered when scaling down the standard cell height is the worsening ratio of active regions to “dead space” or gaps without active regions (e.g., spacing or gaps that may be required by design rules). Using double-height cells may address performance issues for high-current circuits, but scaled down double-height cells may still suffer from a less than optimal ratio of active regions to dead space. Additionally, transition regions, also known as jogs, where there is a transition from one nanoribbon width to another, may be incompatible with some patterning processes. In some cases, not using a jog may also introduce challenges. For example, not using a jog in a double-height cell with a merged nanoribbon, as described in more detail below, may result in a wider than desired nanoribbon, which may in turn increase the strength (e.g., lower the threshold voltage and increase the switching speed) of the nanoribbon-based transistor formed on the basis of the wide nanoribbon.

In some examples, increasing the strength of a given transistor may negatively affect the performance of a circuit. For example, the relative strength of transistors in an inverter circuit, SRAM circuit, or other CMOS circuit may affect operation and/or performance of the circuit. For example, in an SRAM circuit, the pull-down (PD) transistors are typically stronger than the pass gate (PG) transistors to enable a read access, and the PG transistors are typically stronger than the pull-up (PU) transistors to enable a write access. Thus, PU transistors that are much weaker (e.g., 20-30% weaker) than the PD transistors are typically used to ensure read and write stability in the SRAM circuit. Conversely, a PU transistor that is strong relative to a PD transistor may result in a nonoperational or unreliable SRAM circuit. Thus, the increased transistor strength resulting from a wide nanoribbon may be problematic in some circumstances.

In accordance with examples described herein, IC structures including nanoribbon-based transistors fabricated using NP ratio tuning techniques may enable IC structures with the desired transistor strengths while also improving the ratio of active area to dead space in the IC design.

For purposes of illustrating IC structures including nanoribbon-based transistors fabricated using NP ratio tuning techniques, described herein, it might be useful to first understand phenomena that may come into play during IC fabrication. The following foundational information may be viewed as a basis from which the present disclosure may be properly explained. Such information is offered for purposes of explanation only and, accordingly, should not be construed in any way to limit the broad scope of the present disclosure and its potential applications.

Non-planar transistors such as double-gate transistors, trigate transistors, FinFETs, nanowire, and nanoribbon transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors.

A gate enclosure of a transistor refers to a portion of the gate stack which sets the amount of a “top-down” space that a gate stack consumes beyond the channel confinement surface. Conventional non-planar transistor architectures all utilize gate enclosures that not only consume space but also add parasitic capacitance, impacting area scaling, speed improvements, and energy savings. A nanocomb transistor architecture (also sometimes referred to as a forksheet architecture) has been proposed in the literature as a scaling booster to reduce the cell dimensions and parasitic capacitance, where the name “nanocomb/forksheet” arises because of its complex bilateral finned structure. In an example nanocomb transistor arrangement, the nanoribbons are coupled with a dielectric “spine” or wall, and there is no gate enclosure on one of the two sides of the vertical stack of lateral nanoribbons or nanosheets (referred to in the following as “nanoribbons”), while the gate enclosure on the other side still remains. In other examples, a nanocomb transistor arrangement may include a portion of the gate electrode material and/or gate insulator between the dielectric spine and the nanoribbons.

As used herein, the term “nanoribbon” refers to an elongated semiconductor structure having a long axis parallel to a support structure (e.g., a substrate, a chip, or a wafer) over which a transistor arrangement is provided. In some settings, the term “nanoribbon” has been used to describe an elongated semiconductor structure that has a rectangular transverse cross-section (i.e., a cross-section in a plane perpendicular to the longitudinal axis of the structure), while the term “nanowire” has been used to describe a similar structure but with a circular or square-like transverse cross-section. In the present disclosure, the term “nanoribbon” is used to describe both such nanoribbons (including nanosheets) and nanowires, as well as elongated semiconductor structures with a longitudinal axis parallel to the support structures and with having transverse cross-sections of any geometry (e.g., oval, or a polygon with rounded corners). As used herein, the term “face of a nanoribbon” refers to any of the confinement surfaces (i.e., interfaces of the semiconductor material of the nanoribbon with the gate stack) of the nanoribbon which are substantially parallel to the support structure when a nanoribbon extends in a direction parallel to the support structure, while the term “sidewall of a nanoribbon” refers to any of the confinement surfaces of the nanoribbon connecting the bottom face and the top face (the bottom face being the face of the nanoribbon that is closer to the support structure than the top face).

While the descriptions are provided herein with reference to nanoribbons, the principles of IC structures including nanoribbon-based transistors fabricated using NP ratio tuning techniques, described herein, are equally applicable to arrangements where a channel material is shaped as a structure where the length of the structure (e.g., a dimension measured along the y-axis of the example coordinate system shown in the present drawings) is similar to the thickness of the structure (e.g., a dimension measured along the z-axis of the example coordinate system shown in the present drawings).

IC structures as described herein, in particular IC structures including nanoribbon-based transistors fabricated using NP ratio tuning techniques as described herein, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of a radio frequency (RF) receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/-10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of the presence of IC structures including nanoribbon-based transistors fabricated using NP ratio tuning techniques as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices (e.g., physically coupled, conductively coupled, e.g., directly electrically connected). A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

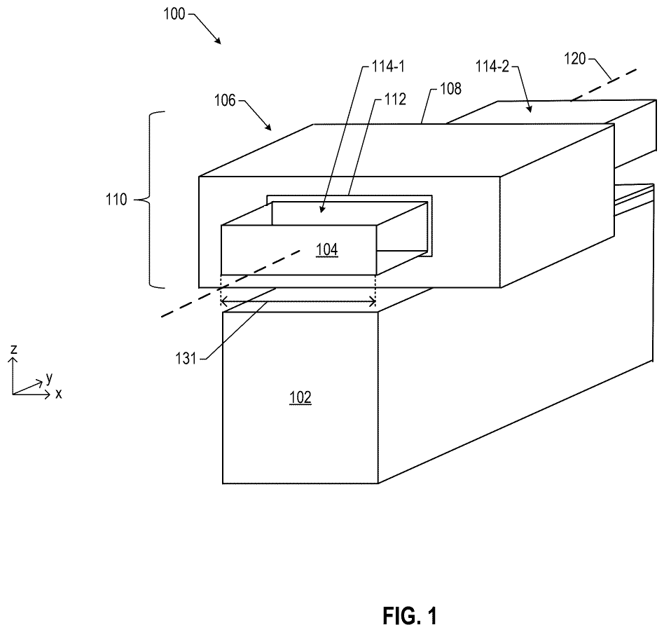

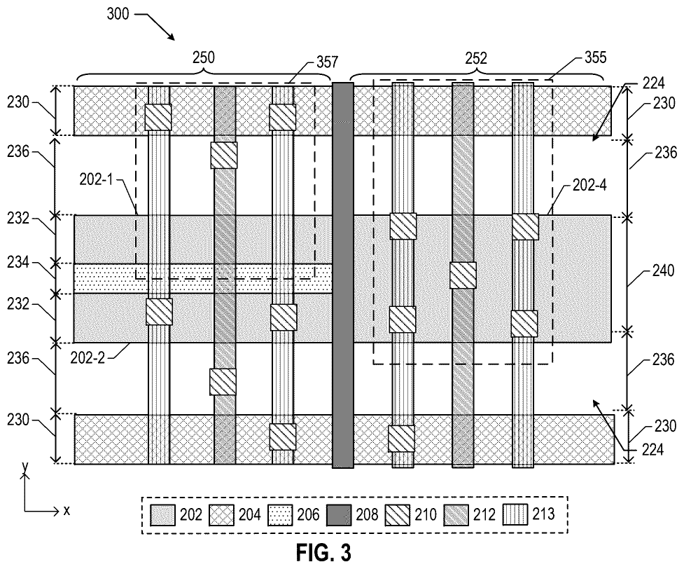

FIG. 1 provides a perspective view of an example IC structure 100 with a nanoribbon transistor 110, according to some embodiments of the present disclosure. For example, in various embodiments, the transistor 110 formed on the basis of a nanoribbon 104, shown in FIG. 1, may be formed on the basis of any of the nanoribbon-based transistor arrangements shown in any of FIGS. 3, 4A-4B, 5A-5B, 6A-6B, and 7A-7B. In some of those examples, the nanoribbon-based transistor arrangement is a nanocomb transistor that is formed in the stacks of lateral nanoribbons separated by a dielectric wall. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2, on either side of the gate stack 106. One of the S/D regions 114-1, 114-2 is a source region and the other one is a drain region. However, because, as is common in the field of FETs, designations of source and drain are often interchangeable, they are simply referred to herein as a first S/D region 114-1 and a second S/D region 114-2.

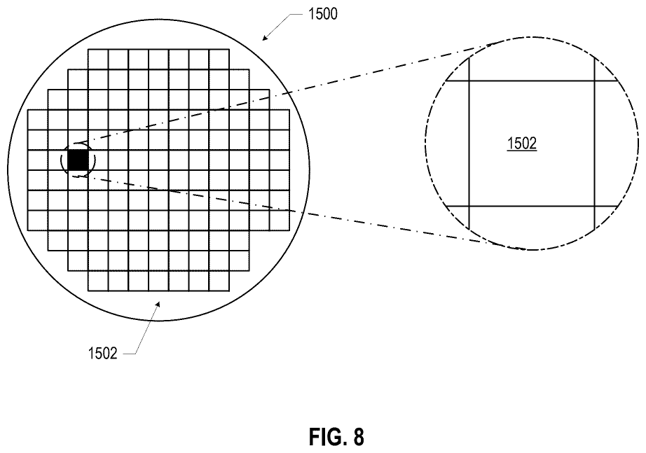

Implementations of the present disclosure may be formed or carried out on any suitable support 102, such as a substrate, a die, a wafer, or a chip. The support 102 may, e.g., be the wafer 1500 of FIG. 8, discussed below, and may be, or be included in, a die, e.g., the singulated die 1502 of FIG. 8, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure including nanoribbon-based transistors fabricated using NP ratio tuning techniques as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. For example, FIGS. 3, 4A-4B, 5A-5B, 6A-6B, and 7A-7B show IC structures that may be or include examples of the IC structure 100. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width 131 of the nanoribbon 104 (i.e., a dimension measured in a plane parallel to the support 102 and in a direction perpendicular to the longitudinal axis 120 of the nanoribbon 104, e.g., along the x-axis of the coordinate system) may be at least about 3 times larger than a height or thickness of the nanoribbon 104 (i.e., a dimension measured in a plane perpendicular to the support 102, e.g., along the z-axis of the coordinate system), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some examples, nanoribbons of the same semiconductor material may be used to form NMOS and PMOS transistors. In such examples, the NMOS and PMOS transistors may be differentiated by depositing N-type or P-type work function metals around channel portions of those transistors.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on back-end fabrication to avoid damaging other components, e.g., front-end components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, tungsten, ruthenium, palladium, platinum, cobalt, nickel, and conductive metal oxides (e.g., ruthenium oxide), conductive metal nitrides (e.g., titanium nitride). For an NMOS transistor, gate electrode materials that may be used in different portions of the gate electrode material 108 include, but are not limited to, tungsten, hafnium, zirconium, titanium, tantalum, aluminum, alloys of these metals, and carbides of these metals (e.g., hafnium carbide, zirconium carbide, titanium carbide, tantalum carbide, and aluminum carbide, titanium aluminum carbide). In one example in which both an NMOS transistor and PMOS transistor include gate electrode materials that include tungsten, the gate electrode material including tungsten for the NMOS transistor may include fluorine, and the gate electrode material including tungsten for the PMOS transistor may be fluorine-free (e.g., fluorine may be substantially absent from a gate electrode material including tungsten for a PMOS transistor). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided below.

Turning to the S/D regions 114-1, 114-2 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. The channel portions of transistors typically include semiconductor materials with doping concentrations significantly smaller than those of the S/D regions 114-1, 114-2.

The S/D regions 114-1, 114-2 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114-1, 114-2. An epitaxial deposition process may then be carried out to fill the recesses with material that is used to fabricate the S/D regions 114-1, 114-2. In some implementations, the S/D regions 114-1, 114-2 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114-1, 114-2 may be formed using one or more alternate semiconductor materials such as germanium or a group III-V material or alloy. And in further embodiments, one or more layers of metal and/or metal alloys may be used to form the S/D regions 114-1, 114-2. In some embodiments, a distance between the first and second S/D regions 114-1 and 114-2 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114-1, 114-2 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

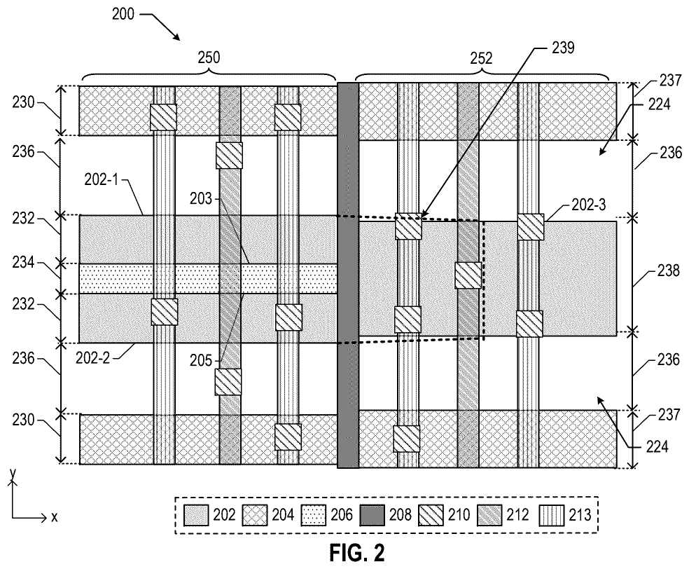

FIG. 2 is a top-down plan view of an example of an IC structure including a double-height merged nanoribbon-based transistor with a jog. A number of elements referred to in the description of FIGS. 2 and 3 with reference numerals are illustrated in these drawings with different patterns, with a legend showing the correspondence between the reference numerals and patterns being provided at the bottom of each drawing page containing FIGS. 2 and 3. For example, the legend illustrates that FIGS. 2 and 3 use different patterns to show an N-type nanoribbon 204 and a P-type nanoribbon 202, and so on.

Referring to FIG. 2, the IC structure 200 includes two stacks of nanoribbons 204 on either side of a stack of nanoribbons 202. The following description refers to the nanoribbons 204 as N-type nanoribbons that form the basis of NMOS transistors and the nanoribbons 202 as P-type nanoribbons that form the basis of PMOS transistors. In some examples, the N-type and P-type nanoribbons 204, 202 may have the same or substantially the same material composition. In one such example, the NMOS and PMOS transistors may be distinguished from one another based on the presence of one or more different gate electrode materials in their respective gate stacks.

The IC structure 200 illustrated in FIG. 2 includes a first portion or region 250 and a second portion or region 252. In the first region 250, a dielectric wall 206 is present in the stack of P-type nanoribbons 202. The dielectric wall 206 (which may also be referred to as a spine or backbone) may be a portion of a dielectric material that is substantially shaped like a wall that extends substantially orthogonally from the substrate. The dielectric wall 206 may extend through the stack of nanoribbons 202 in the region 250, such that portions of the nanoribbons 202 on either side of the dielectric wall 206 may be referred to as separate stacks of nanoribbons. For example, the nanoribbons 202 in the region 250 may be referred to as first nanoribbons 202-1 coupled with a first face or side 203 of the dielectric wall 206 and second nanoribbons 202-2 coplanar with the first nanoribbons 202-1 and coupled with a second face or side 205 of the dielectric wall 206. The nanoribbons 202-1, 202-2, and the dielectric wall 206 may form the basis of one or more nanocomb transistors in the region 250. The dielectric wall is absent from the portion of the P-type nanoribbon in the region 252 (e.g., a dielectric wall is absent from the nanoribbon 202-3 in the region 252). Accordingly, the nanoribbons 202-1, the nanoribbons 202-2, and the nanoribbons 202-3 may be considered different portions of a same nanoribbon stack, where a dielectric wall 206 is present in the stack in the region 250. In other examples, the nanoribbon 202-1 may be separated from the nanoribbon 202-2 by a space or gap (e.g., the dielectric wall 206 may represent a gap between two nanoribbons without active devices that may be filled with, e.g., a gate electrode material and/or insulator material). In one such example, the nanoribbons 202-1 and 202-2 may be surrounded by the gate electrode material on four sides instead of being in contact with the dielectric wall 206 on one side.

In the example illustrated in FIG. 2, the N-type nanoribbons 204 are separated from the P-type nanoribbon 202 by a space or gap 224, where the gap 224 may be a region without active devices. Metal gate lines 212 and S/D contact lines 213 may extend substantially perpendicular to the nanoribbons 202 and 204 and substantially parallel to one another, e.g., along the y-axis shown in FIG. 2. FIG. 2 illustrates that the metal gate lines 212 and the S/D contact lines 213 may be provided in an alternating manner. Metal gate lines 212 may intersect gate contacts that are in conductive contact with the gate stacks 106 (not visible in the view of FIG. 2) provided over channel portions of the nanoribbons 202 and 204, providing electrical connectivity to the gates of the nanoribbon transistors. Thus, portions of the gate contacts intersecting the gate stacks 106 are in conductive contact with the gate stacks 106 and serve as gate contacts for the transistors. Similarly, S/D contact lines 213 may intersect the S/D contacts provided over S/D regions 114-1, 114-2 (not visible in the view of FIG. 2) of the nanoribbons 202 and 204, providing electrical connectivity to the S/D regions 114-1, 114-2 of the nanoribbon transistors. Thus, portions of the S/D contacts intersecting the S/D regions 114-1, 114-2 are in conductive contact with the S/D regions 114-1, 114-2 and serve as S/D contacts for the transistors. Conductive vias 210 may couple the metal gate lines 212 and the S/D contact lines 213 with conductive lines in a metal layer over the device region of the IC structure 200. One or more isolation lines, such as the isolation region 208, may also be present in the IC structure. In one example, such isolation lines may be substantially parallel with the metal gate lines 212 and substantially orthogonal to the nanoribbons 202 and 204.

As mentioned briefly above, circuit design may be done using cells from a library. For example, referring to FIG. 2, the boundaries of a cell (e.g., a standard or single height cell or double-height cell) may be located at or between the boundary between an N-type diffusion region and a P-type diffusion region (e.g., between or at a boundary between an N-type nanoribbon and P-type nanoribbon). As used herein, the term double-height cell refers to a cell with a greater height (which may translate to a greater width of the nanoribbon in the cell) than a standard height cell. In the example illustrated in FIG. 2, the nanoribbons 204 in the region 250 have a width 230, and the nanoribbons 202-1 and 202-2 have a width 232. The dielectric wall 206 (or, in an IC structure in which the region of the dielectric wall 206 represents a gap between the two nanoribbons 202-1 and 202-2) has a width 234. The gaps 224 between the nanoribbons 204 and the adjacent nanoribbons 202 have a width of 236. In one example, the width 230 of the N-type nanoribbon 204 and the width 232 of the P-type nanoribbons 202-1 and 202-2 that are coupled with the dielectric wall 206 have about the same width. In the region 252 in FIG. 2, the nanoribbon 202-3 has a width 238. In the example illustrated in FIG. 2, the width 238 of the nanoribbon 202-3 is greater than or equal to the width 232 of the nanoribbon 202-1 plus the width 232 of the nanoribbon 202-2 (e.g., greater than or equal to about twice the width 232). In the example illustrated in FIG. 2, the width 238 of the nanoribbon 202-3 is smaller than the combined width of the nanoribbons 202-1 and 202-2 and the dielectric wall 206 (e.g., smaller than the width 232 plus the width 232 plus the width 234). Thus, in the example illustrated in FIG. 2, there is a transition region or “jog” in the IC structure, as shown with the dotted line 239. In the example in FIG. 2, the spacing between nanoribbons is the same in both the regions 250 and 252. Therefore, the nanoribbons 204 have a greater width 237 in the region 252 than in the region 250 (e.g., the width 237 is greater than the width 230).

As can be seen in FIG. 2, the nanoribbon 202-3 has a width 238 as if two nanoribbons were merged together. For example, the nanoribbon 202-3 may occupy the space (e.g., width) similar to the nanoribbons 202-1 and 202-2 and some of the dielectric wall 206. The wide nanoribbon 202-3 may be the basis in which higher performance transistors are formed. The ratio of active regions to dead space may also improved in the region 252 compared to a region without a merged nanoribbon along the same nanoribbon path as a nanocomb transistor. As a result of the jog in the IC structure 200, the width 238 of the nanoribbon 202-3 is wider than the width 232, and can be designed to achieve the desired transistor strength in the region 252. A jog with a greater slope or angle (e.g., angle relative to the length of the nanoribbon 202-1, or the x-axis as shown in FIG. 2) may be used to reduce the width 238, and a jog with a smaller slope or angle may be used to increase the width 238 of the nanoribbon 202-3. As mentioned briefly above, using a jog in an IC design may limit the processes (e.g., patterning processes) that may be used.

In contrast, FIG. 3 illustrates a top-down plan view of an example of an IC structure 300 including a merged nanoribbon-based transistor without a jog. The IC structure 300 is similar to the IC structure 200 of FIG. 2 with the exception of the nanoribbon widths in the region 252 due to the absence of a jog in the IC structure. As mentioned above, in FIG. 2, the width 238 of the nanoribbon 202-3 is greater than the combined width of the nanoribbons 202-1 and 202-2, but less than the combined width of the nanoribbons 202-1 and 202-2 and the dielectric wall 206. In contrast, in FIG. 3, the width 240 of the nanoribbon 202-4 is equal (e.g., substantially equal) to the width 232 of the nanoribbon 202-1 plus the width 234 of the dielectric wall 206 (or gap between the nanoribbons 202-1 and 202-2) plus the width 232 of the nanoribbon 202-2. Like in FIG. 2, adjacent nanoribbons 202 and 204 are separated by about the same distance (e.g., the gaps 224 between adjacent nanoribbons 202 and 204 have about the same width 236). Therefore, given the wider nanoribbon 202-4 in FIG. 3, the nanoribbons 204 in the region 252 have about the same width 230 as the nanoribbons 204 in the region 250 (unlike in FIG. 2 where the width 237 of the nanoribbons 204 in the region 252 is greater than the width 230 of the nanoribbons 204 in the region 250).

Thus, as a result of the absence of a jog, the width 240 of the merged nanoribbon 202-4 is greater in FIG. 3 than the width 238 of the merged nanoribbon 202-3 in FIG. 2. Thus, in the example illustrated in FIG. 3, the width of the P-type nanoribbon 202-4 is two times the total width of the two N-type nanoribbons 204. In some examples, the greater width 238 may result in a stronger nanoribbon-based transistor (e.g., a stronger PMOS transistor) formed on the basis of the nanoribbon 202-4, which may be problematic in some circuits.

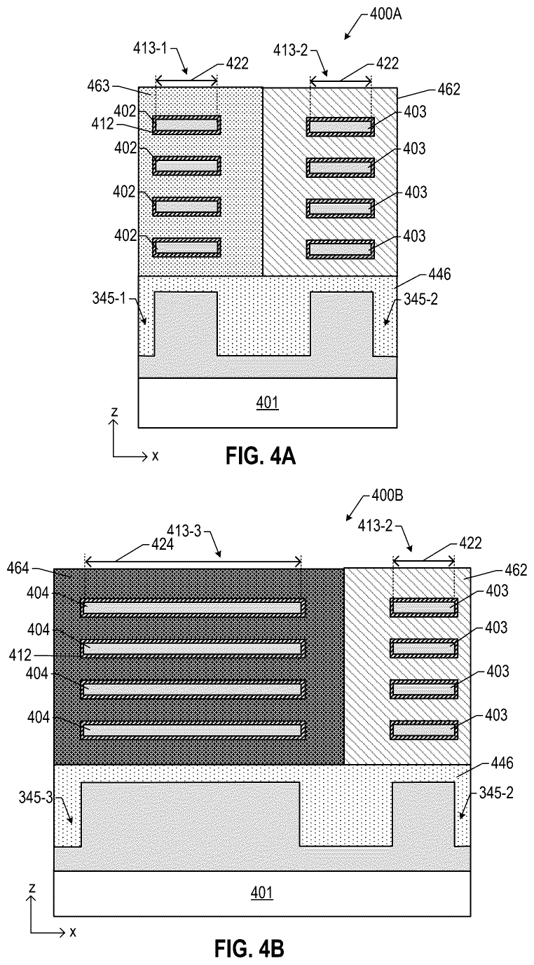

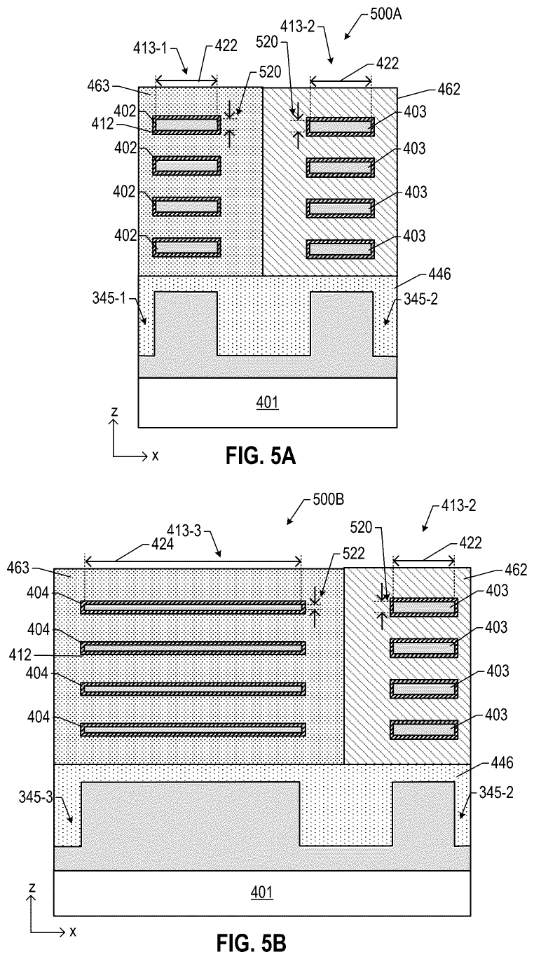

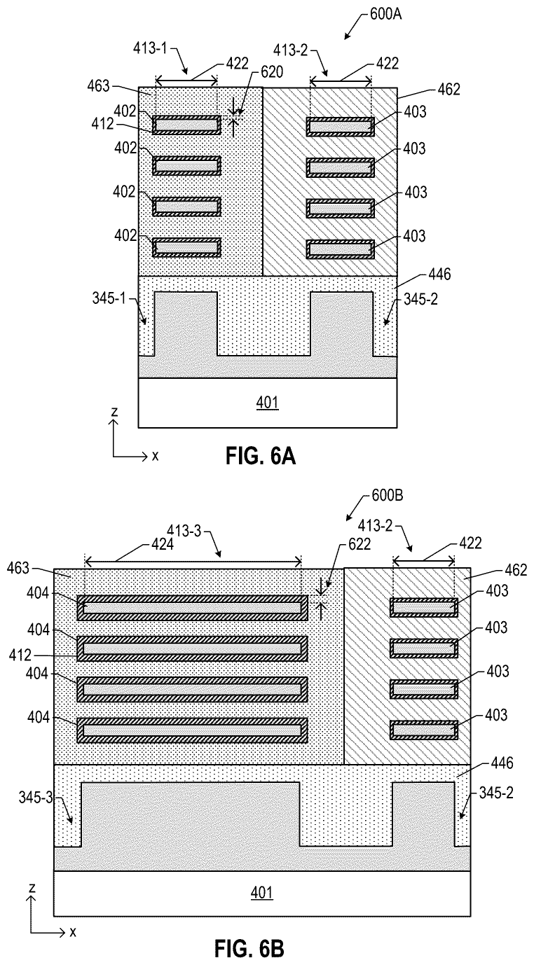

According to examples described herein, NP ratio tuning techniques may be used to achieve the desired transistor strength in IC structures with merged nanoribbon-based transistors without a jog. In one example, an IC structure may include a different gate electrode material around the wider portion of the nanoribbon (e.g., around the nanoribbon 202-4 in the region 252) than around the narrower portion of the nanoribbon (e.g., around the nanoribbon 202-1 and/or the nanoribbon 202-2 in the region 250) (e.g., as illustrated in FIGS. 4A-4B). In another example, the wider portion of the nanoribbon may have a smaller thickness than the narrower portion of the nanoribbon (e.g., as illustrated in FIGS. 5A-5B). In another example, the gate dielectric material may be thicker around the wider portion of the nanoribbon than around the narrower portion of the nanoribbon (e.g., as illustrated in FIGS. 6A-6B). One or more of these techniques may be used to adjust the strength of a nanoribbon (e.g., the P-type nanoribbon 202-4) to achieve a desired NP ratio with or without using a jog in the IC circuit design. FIGS. 4A-4B, 5A-5B, and 6A-6B illustrate example regions of IC structures with nanoribbon stacks, which may form the basis of NMOS nanoribbon-based transistors and PMOS nanoribbon-based transistors. The figures labeled with an “A” (e.g., FIG. 4A) show a cross-section of an IC structure in a region with narrower P-type nanoribbons, such as in the region 357 of FIG. 3 (identified with a dashed line). The figures labeled with a “B” (e.g., FIG. 4B) show another cross-section of another region of the same IC structure with wider (e.g., merged) P-type nanoribbons, such as in the region 355 of FIG. 3 (identified with a dashed line).

Turning first to FIG. 4A, the IC structure 400A includes a first stack 413-1 of nanoribbons 402 of a semiconductor material and a second stack 413-2 of nanoribbons 403 of a semiconductor material adjacent to the first stack 413-1 and over a support 401. FIG. 4B illustrates an IC structure 400B with the stack 413-2 of nanoribbons 403 and a stack 413-3 of nanoribbons 404. The support 401 may be an example of the support 102 of FIG. 1. The nanoribbons 402, 403, and 404 may be examples of the nanoribbon 104 of FIG. 1. While FIGS. 4A-4B and subsequent drawings illustrate four nanoribbons in each of the stacks 413-1 and 413-2, embodiments of the present disclosure include IC structures having more or fewer stacked nanoribbons than depicted. The semiconductor material of the nanoribbons 402 and 403 may be any of the semiconductor/channel materials described above with reference to the nanoribbon 104 of FIG. 1. In some examples, the nanoribbons 402 may be adjacent to and/or in contact with a dielectric wall or spine to form a nanocomb transistor. In one such example, the dielectric wall or spine may be along a same line as the nanoribbons 404.

Although FIGS. 4A and 4B label the stacks 413-1, 413-3 with different reference numbers and the nanoribbons 402, 404 with different reference numbers, the stack 413-3 may represent a different portion of the same stack as 413-1, and the nanoribbons 404 may represent different portions of the nanoribbons 402. For example, a nanoribbon of the stack 413-1 and a nanoribbon of the stack 413-3 may be coplanar with one another, parallel with one another, and extending along the same line or ribbon path. In the example illustrated in FIGS. 4A-4B, the nanoribbons 402 and the nanoribbons 403 have a width 422, where the width 422 is a dimension of the nanoribbons 402, 403 in a plane substantially parallel with the substrate or support 401. Although FIG. 4A depicts the nanoribbons 402 and 403 as having the same widths, in other examples, the width of the nanoribbons 402 may be different from the width of the nanoribbons 403. The nanoribbons 404 have a width 424, where the width 424 of the nanoribbons 404 is greater than the width 422 of the nanoribbons 402.

The IC structures 400A and 400B also include subfins 345-1, 345-2, and 345-3 including a first subfin 345-1 below and substantially aligned with the first stack 413-1 of nanoribbons 402, a second subfin 345-2 below and substantially aligned with the second stack 413-2 of nanoribbons 403, and a third subfin 345-3 below and substantially aligned with the third stack 413-3 of nanoribbons 404. In some examples, the subfins 345-1, 345-2, 345-3 may include subfin replacement structures of an insulator material; in other examples, the subfins 345-1, 345-2, 345-3 may include subfin structures that include the semiconductor material of the nanoribbons 402, 403, 404 and/or include semiconductor materials of different material compositions. In the example illustrated in FIGS. 4A-4B, an insulator material 446 lines the shallow trench insulator (STI) region between the subfins 345-1, 345-2 and between the subfins 345-3, 345-2. In some examples, the insulator material 446 may be an oxide (e.g., silicon oxide, silicon oxynitride, carbon-doped silicon oxide, carbon-doped silicon oxynitride, or another suitable insulator material including oxygen).

A gate stack having a gate insulator material 412 and one or more gate electrode materials wraps around channel portions of the nanoribbons 402, 403, and 404. The gate insulator material 412 may be an example of the gate insulator material 112 of FIG. 1. In some embodiments, the gate insulator material 412 may be absent in the IC structure. As mentioned above, in some examples, NMOS and PMOS nanoribbon-based transistors may be formed with the same channel materials and different gate electrode materials (e.g., one or more different work function metals). For example, FIG. 4A illustrates an example of a first gate electrode material 463 (e.g., one or more first PMOS work function metals, e.g., one or more P-type work function metals suitable for PMOS devices) at least partially around the nanoribbons 402. The IC structure 400A includes a second gate electrode material 462 (e.g., one or more NMOS work function metals, e.g., one or more N-type work function metals suitable for NMOS devices) at least partially around the nanoribbons 403. In one example, gate electrode material 462, which may be for an NMOS device, may include metal carbide (e.g., includes one or more metals and carbon), tungsten, or another suitable conductive material. In one example, the gate electrode material 463, which may be for a PMOS device, may include titanium and nitrogen (e.g., titanium nitride), tungsten, or another suitable conductive material for forming a gate electrode for a PMOS transistor. In some examples, the gate electrode material 463 is in contact with (e.g., in direct contact with such that there is no intervening material) the gate electrode material 462 between the stack 413-1 and the stack 413-2. In the example illustrated in FIG. 4A, a first transistor may be formed in the stack 413-1 with a first channel region in portions of the nanoribbons 402 and a second transistor may be formed in the stack 413-2 with a second channel region in portions of the nanoribbons 403. In one such example, the first transistor includes the gate electrode material 463 at least partially around the first channel region, and the second transistor includes the gate electrode material 462 at least partially around the second channel region.

In the example illustrated in FIG. 4B, the IC structure 400B includes a different gate electrode material 464 (e.g., a different PMOS work function metal) around the nanoribbons 404 with a wider width 424. In one example, the gate electrode material 464 has a different material composition than the gate electrode material 463 and the gate electrode material 462. In one such example, the gate electrode material 464 includes a metal (such as tungsten and/or titanium), nitrogen, and a P dipole material. In one such example, the gate electrode material 463 includes a metal (e.g., tungsten and/or titanium) and nitrogen, but lacks the P dipole material that is present in the gate electrode material 464. For example, the gate electrode material 464 may include aluminum, and aluminum may be substantially absent from the gate electrode material 463. In one example, a material may be substantially absent if it is present below typical impurity concentrations, e.g., below about 10¹⁵ atoms per cubic centimeter (cm⁻³) or below 10¹³ cm⁻³. In some examples, the P dipole material or other material that is present in the gate electrode material 464 and absent from the gate electrode material 463 (such as aluminum or another suitable material) may be present in the gate electrode material 462. Thus, in one example, a first gate electrode material 463 may be around a first portion of a nanoribbon (e.g., the nanoribbons 402), and a second gate electrode material 464 may be around a different portion of the nanoribbon with a greater width (e.g., the nanoribbons 404). In one such example, a third gate electrode material 462 may be around an adjacent coplanar nanoribbon (e.g., the nanoribbons 403). In one such example, the third gate electrode material may be in contact with both the first gate electrode material and the second gate electrode material. In one such example, the different gate electrode material 464 around the nanoribbons 404 may increase the threshold voltage of the transistor with a channel region in the nanoribbons 404. Thus, in one example, the ratio of the threshold voltages of a PMOS transistor with a channel region in the nanoribbons 404 and an NMOS transistor with a channel region in the nanoribbons 403 may be tuned with the use of a different gate electrode material 464 (e.g., different relative to the gate electrode material 463).

FIGS. 5A-5B illustrate another example of IC structures including a double-height merged nanoribbon-based transistor fabricated using NP ratio tuning techniques. Turning to FIG. 5A, the IC structure 500A may be the same or similar to the IC structure 400A of FIG. 4A. For example, the IC structure includes a stack 413-1 of nanoribbons 402 adjacent to a stack 413-2 of nanoribbons 403. Similarly, as shown in FIG. 5B, the IC structure 500B is similar to the IC structure 400B, with a stack 413-3 of wide nanoribbons 404. However, a difference in the IC structure 500B compared to the IC structure 400B is that the nanoribbons 404 are thinner than the nanoribbons 402 (and thinner than the nanoribbons 403). For example, the nanoribbons 402 have a first thickness 520, the nanoribbons 403 have the thickness 520, and the nanoribbons 404 have a thickness 522, which is smaller than the thickness 520 (where the thicknesses 520 and 522 are dimensions of the nanoribbons 402 and 404, respectively, in a plane substantially orthogonal to the substrate or support 401, e.g., along the z-axis as shown in FIGS. 5A-5B). In one example, the thickness 522 is about 10-30 percent smaller than the thickness 520 (or about 15-35% smaller, or about 18 to 22% smaller). In one example, the thickness 522 is about 0.5 to 1.5 nanometers smaller than the thickness 520. In one such example, the thickness 520 may be in a range of about 4 to 6 nanometers (or about 4.5 to 5.5 nanometers), and the thickness 522 may be in a range of about 3 to 5 nanometers (or about 3.5 to 4.5 nanometers).

Another difference in the example illustrated in FIG. 5B compared to the IC structure 400B of FIG. 4B is that the gate electrode material 463 around the nanoribbons 404 is the same gate electrode material 463 around the nanoribbons 402. In other examples, the gate electrode material around the nanoribbons 404 may be different from the gate electrode material 463 around the nanoribbons 402. In one example, the portion of the nanoribbons that are wider and thinner (e.g., the nanoribbons 404) and the portion of the nanoribbons that are thicker and narrower (e.g., the nanoribbons 402) may be nanoribbons for a PMOS transistor and the nanoribbons 403 may be nanoribbons for an NMOS transistor. In one example, by decreasing the thickness of the wide portion of the nanoribbons (e.g., the nanoribbons 404), the ratio of the threshold voltages of a PMOS transistor with a channel region in the nanoribbons 404 and an NMOS transistor with a channel region in the nanoribbons 403 may be tuned.

FIGS. 6A-6B illustrate another example of IC structures including a double-height merged nanoribbon-based transistor fabricated using NP ratio tuning techniques. Turning to FIG. 6A, the IC structure 600A may be the same or similar to the IC structure 400A of FIG. 4A. For example, the IC structure includes a stack 413-1 of nanoribbons 402 adjacent to a stack 413-2 of nanoribbons 403. Similarly, as shown in FIG. 6B, the IC structure 600B is similar to the IC structure 600B, with a stack 413-3 of wide nanoribbons 404. However, a difference in the IC structure 600B compared to the IC structure 400B is that the gate dielectric material 412 around the nanoribbons 404 is thicker than the gate insulator material 412 around the nanoribbons 402. For example, the IC structure 400B includes a gate electrode material 463 at least partially around the nanoribbons 404 and a gate dielectric material 412 with a thickness 622 between the semiconductor material of the nanoribbon 404 and the gate electrode material 463. The IC structure 400A includes a gate electrode material 463 at least partially around the nanoribbons 402 and a gate dielectric material 412 with a thickness 620 between the gate electrode material 463 and the semiconductor material of the nanoribbons 402. In one example, the gate dielectric material 412 is at least partially around the nanoribbons 404 and at least partially around the nanoribbons 402. In one example, the thickness 622 of the gate insulator material 412 around the nanoribbons 404 is greater than the thickness 620 of the gate insulator material 412 around the nanoribbons 402. In one example, the thickness 622 is about 25 to 35 percent greater than the thickness 620. In one example, the thickness 622 is about 0.2 to 0.4 nanometers greater than the thickness 620.

Another difference in the example illustrated in FIG. 6B compared to the IC structure 400B of FIG. 4B is that the gate electrode material 463 around the nanoribbons 404 is the same gate electrode material 463 around the nanoribbons 402. In other examples, the gate electrode material around the nanoribbons 404 may be different from the gate electrode material 463 around the nanoribbons 402. In one example, the portion of the nanoribbons that are wider and at least partially surrounded by a thicker gate dielectric material (e.g., the nanoribbons 404) and the portion of the nanoribbons that are narrower and surrounded by a thinner gate dielectric material (e.g., the nanoribbons 402) may be nanoribbons for a PMOS transistor and the nanoribbons 403 may be nanoribbons for an NMOS transistor. In one example, by increasing the thickness of the gate dielectric material around the wide portion of the nanoribbons (e.g., the nanoribbons 404), the ratio of the threshold voltages of a PMOS transistor with a channel region in the nanoribbons 404 and an NMOS transistor with a channel region in the nanoribbons 403 may be tuned.

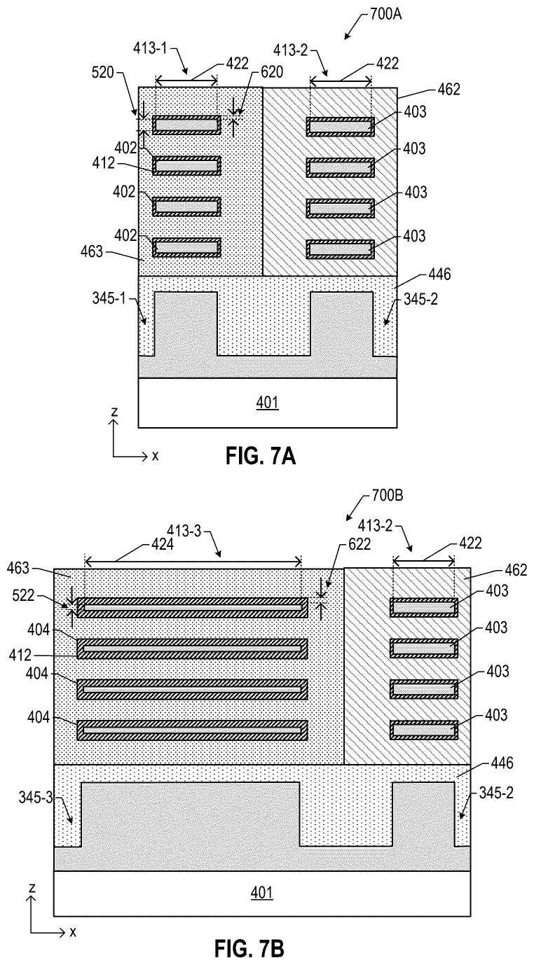

As mentioned above, two or more of the NP tuning techniques described herein may be combined. For example, FIGS. 7A-7B illustrate example IC structures 700A and 700B in which the nanoribbons 404 are thinner than the nanoribbons 402, and the gate dielectric material 412 around the nanoribbons 404 is thicker than the gate dielectric material 412 around the nanoribbons 402. In another example, any one of the IC structures illustrated in FIGS. 5A-5B, 6A-6B, and 7A-7B may have a different gate electrode material around the nanoribbons 404 than around the nanoribbons 402, such as described above with respect to FIGS. 4A-4B.

IC structures including nanoribbon-based transistors fabricated using NP ratio tuning techniques, in accordance with examples described herein (e.g., as described with reference to FIGS. 1, 3, 4A-4B, 5A-5B, 6A-6B, and 7A-7B) may be used to implement any suitable components. For example, in various embodiments, transistors described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC structures disclosed herein, e.g., the IC structures 100, 300, 400A, 400B, 500A, 500B, 600A, 600B, 700A, and 700B, may be included in any suitable electronic component. FIGS. 8-12 illustrate various examples of apparatuses that may include the IC structures 100, 300, 400A, 400B, 500A, 500B, 600A, 600B, 700A, and 700B disclosed herein.

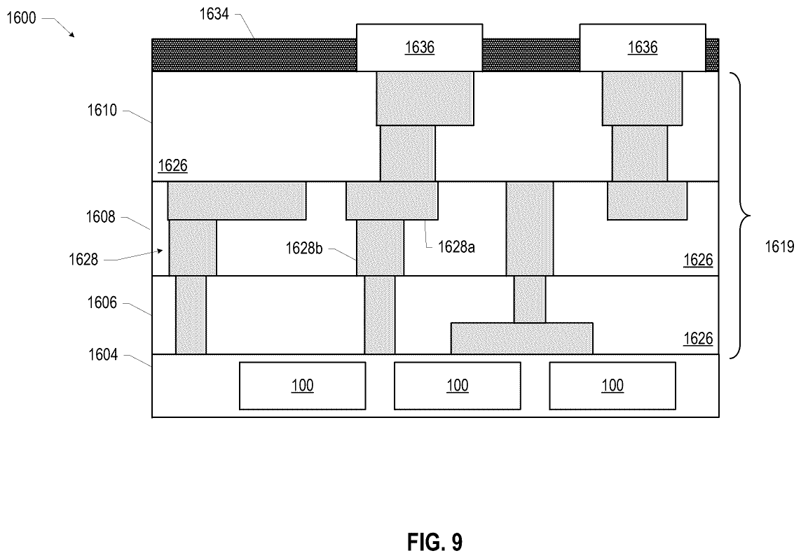

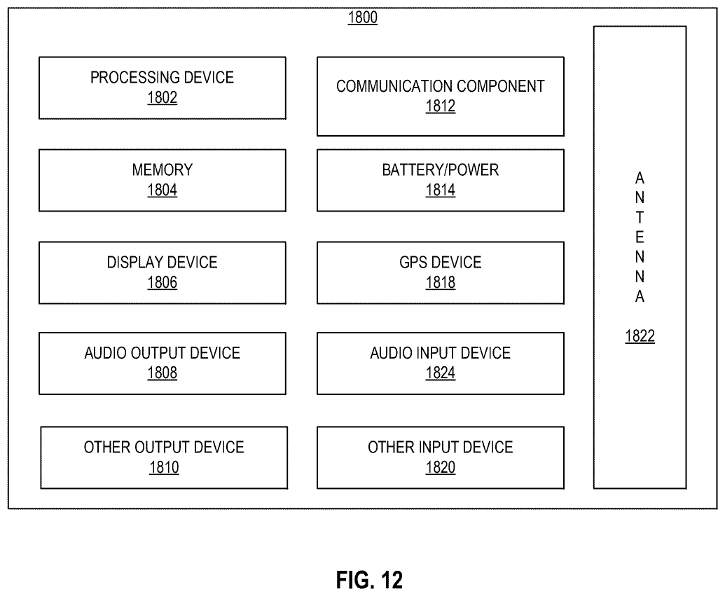

FIG. 8 is a top view of a wafer 1500 and dies 1502 that may include one or more IC structures 100, 300, 400A, 400B, 500A, 500B, 600A, 600B, 700A, and 700B in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures 100, 300, 400A, 400B, 500A, 500B, 600A, 600B, 700A, and 700B (e.g., as discussed below with reference to FIG. 9), one or more transistors (e.g., some of the transistors of the device region 1604 of FIG. 9, discussed below, e.g., nanoribbon-based transistors of the IC structures 100, 300, 400A, 400B, 500A, 500B, 600A, 600B, 700A, and 700B) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 12) or other logic that is configured to store information in the memory devices or execute instructions stored in the memory array.

FIG. 9 is a side, cross-sectional view of an IC device 1600 that may include one or more IC structures in accordance with any of the embodiments disclosed herein (e.g., in accordance with IC structures 100, 300, 400A, 400B, 500A, 500B, 600A, 600B, 700A, and 700B). One or more of the IC devices 1600 may be included in one or more dies 1502 (FIG. 8). The IC device 1600 may include a device region 1604 including one or more IC structures (e.g., one or more of IC structures 100, 300, 400A, 400B, 500A, 500B, 600A, 600B, 700A, and 700B) disclosed herein, or any variations of the IC structures. The device region 1604 may further include electrical contacts to the gates of the transistors included in the device region 1604 and to the S/D materials of the transistors included in the device region 1604 (e.g., to the S/D regions 114-1, 114-2 of the IC structure 100).

Electrical signals, such as power and/or input/output (I/O) signals, may be routed to and/or from the devices (e.g., the transistors) of the device region 1604 through one or more interconnect layers disposed on the device region 1604 (illustrated in FIG. 9 as interconnect layers 1606-1610). For example, electrically conductive features of the device region 1604 (e.g., the gate electrode material 108 of the IC structure 100) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 9). Although a particular number of interconnect layers 1606-1610 is depicted in FIG. 9, embodiments of the present disclosure include IC structures having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the support 102 upon which the device region 1604 is formed. For example, the lines 1628a may route electrical signals in a direction in and out of the page from the perspective of FIG. 9. The vias 1628b may be arranged to route electrical signals in a direction of a plane that is substantially perpendicular to the surface of the support 102 upon which the device region 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 9. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 may be formed above the device region 1604. In some embodiments, the first interconnect layer 1606 may include lines 1628a and/or vias 1628b, as shown. The lines 1628a of the first interconnect layer 1606 may be coupled with contacts (e.g., contacts to the S/D regions 114-1, 114-2 of the IC structure 100) of the device region 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device region 1604) may be thicker.

The IC device 1600 may include a solder resist material 1634 (e.g., polyimide or similar material) and one or more conductive contacts 1636 formed on the interconnect layers 1606-1610. In FIG. 9, the conductive contacts 1636 are illustrated as taking the form of bond pads. The conductive contacts 1636 may be electrically coupled with the interconnect structures 1628 and configured to route the electrical signals of the transistor(s) of the device region 1604 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

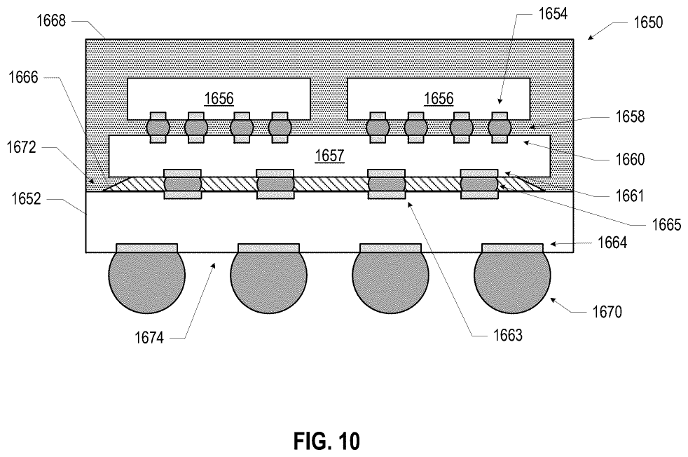

FIG. 10 is a side, cross-sectional view of an example IC package 1650 that may include one or more IC structures 100, 300, 400A, 400B, 500A, 500B, 600A, 600B, 700A, and 700B in accordance with any of the embodiments disclosed herein. In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674. These conductive pathways may take the form of any of the interconnect structures 1628 discussed above with reference to FIG. 9.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 10 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 10 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

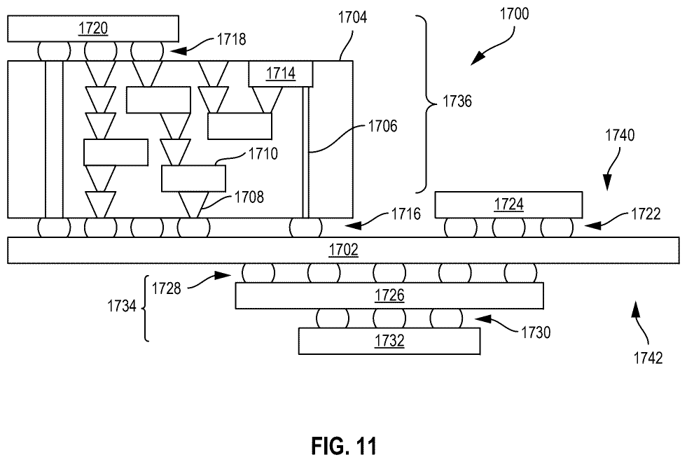

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 10 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 11.

The dies 1656 may take the form of any of the embodiments of the die 1502 discussed herein (e.g., may include any of the embodiments of the IC device 1600). In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 10 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 10, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 11 is a side, cross-sectional view of an IC device assembly 1700 that may include one or more IC packages or other electronic components (e.g., a die) including one or more IC structures 100, 300, 400A, 400B, 500A, 500B, 600A, 600B, 700A, and 700B in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 10 (e.g., may include one or more IC structures 100, 300, 400A, 400B, 500A, 500B, 600A, 600B, 700A, and 700B).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 11 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 11), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 11, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 8), an IC device (e.g., the IC device 1600 of FIG. 9), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 11, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 11 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 12 is a block diagram of an example electrical device 1800 that may include one or more IC structures 100, 300, 400A, 400B, 500A, 500B, 600A, 600B, 700A, and 700B in accordance with any of the embodiments disclosed herein. For example, any suitable ones of the components of the electrical device 1800 may include one or more of the IC device assemblies 1700, IC packages 1650, IC devices 1600, or dies 1502 disclosed herein. A number of components are illustrated in FIG. 12 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 12, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic RAM (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic RAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP 2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a first nanoribbon of a semiconductor material over a substrate, where: the first nanoribbon has a first width, where the first width is a first dimension of the first nanoribbon in a plane substantially parallel with the substrate; a first gate electrode material at least partially around the first nanoribbon; a second nanoribbon of the semiconductor material over the substrate, where: the second nanoribbon is coplanar with and substantially parallel with the first nanoribbon, and extending along a same line as the first nanoribbon, the second nanoribbon has a second width, where the second width is a second dimension of the second nanoribbon in the plane, and the first width is greater than the second width; and a second gate electrode material at least partially around the second nanoribbon, where the second gate electrode material has a different material composition than the first gate electrode material.

Example 2 provides the IC structure of example 1, where: the first gate electrode material includes a metal and nitrogen, and the second gate electrode material includes the metal, nitrogen, and a P dipole material.

Example 3 provides the IC structure of any one of examples 1-2, where: the first gate electrode material and the second gate electrode material include one or more of titanium and tungsten.

Example 4 provides the IC structure of example 3, where: the second gate electrode material includes aluminum.

Example 5 provides the IC structure of example 4, where: aluminum is substantially absent from the first gate electrode material.

Example 6 provides the IC structure of any one of examples 1-5, further including a third nanoribbon (e.g., NMOS nanoribbon) adjacent to and substantially coplanar with the first nanoribbon and the second nanoribbon; and a third gate electrode material at least partially around the third nanoribbon, where the third gate electrode material has a different material composition from the first gate electrode material and the second gate electrode material.

Example 7 provides the IC structure of example 6, where: the third gate electrode material includes titanium, aluminum, and carbon.

Example 8 provides the IC structure of any one of examples 1-7, where: the first nanoribbon has a first thickness, the second nanoribbon has a second thickness, and the first thickness is smaller than the second thickness.

Example 9 provides the IC structure of any one of examples 1-8, where: a gate dielectric material is thicker around the first nanoribbon than around the second nanoribbon.

Example 10 provides an IC structure, including a first nanoribbon of a semiconductor material over a substrate, where: the first nanoribbon has a first width and a first thickness, the first width is a first dimension of the first nanoribbon in a first plane substantially parallel with the substrate, and the first thickness is second dimension of the first nanoribbon in a second plane substantially orthogonal to the substrate; and a second nanoribbon of the semiconductor material over the substrate, where: the second nanoribbon is coplanar with and substantially parallel with the first nanoribbon, and extending along a same line as the first nanoribbon, the second nanoribbon has a second width and a second thickness, the second width is a third dimension of the second nanoribbon in the first plane, the second thickness is a fourth dimension of the second nanoribbon in a third plane substantially orthogonal to the substrate, the first width is greater than the second width, and the first thickness is smaller than the second thickness.

Example 11 provides the IC structure of example 10, where: the first thickness is about 10-30 percent smaller than the second thickness (or about 15-35% or about 18 to 22% smaller).

Example 12 provides the IC structure of any one of examples 10-11, where; the first thickness is about 0.5 to 1.5 nanometers smaller than the second thickness.

Example 13 provides the IC structure of any one of examples 10-12, where: the second thickness is in a range of about 4 to 6 nanometers (or about 4.5 to 5.5 nanometers).

Example 14 provides the IC structure of any one of examples 10-13, further including a first gate dielectric material at least partially around the first nanoribbon; and a second gate dielectric material at least partially around the second nanoribbon, where: the first gate dielectric material is thicker than the second gate dielectric material.

Example 15 provides the IC structure of example 14, where: the first gate dielectric material has a same material composition as the second gate dielectric material.

Example 16 provides the IC structure of any one of examples 14-15, further including a first gate electrode material over the first gate dielectric material; and a second gate electrode material over the second gate dielectric material, where: the first gate electrode material has a different material composition from the second gate electrode material.

Example 17 provides an IC structure, including a first nanoribbon of a semiconductor material over a substrate, where the first nanoribbon has a first width; a first gate electrode material at least partially around the first nanoribbon; a first gate dielectric material with a first thickness between the first nanoribbon and the first gate electrode material; a second nanoribbon of the semiconductor material over the substrate, where: the second nanoribbon is coplanar with and substantially parallel with the first nanoribbon, and extending along a same line as the first nanoribbon, the second nanoribbon has a second width, and the first width is greater than the second width; a second gate electrode material at least partially around the second nanoribbon; and a second gate dielectric material with a second thickness between the second nanoribbon and the second gate electrode material, where the first thickness is greater than the second thickness.

Example 18 provides the IC structure of example 17, where: the second gate electrode material has a different material composition than the first gate electrode material.

Example 19 provides the IC structure of any one of examples 17-18, where: the first thickness is about 25 to 35 percent greater than the second thickness.

Example 20 provides the IC structure of any one of examples 17-19, where: the first thickness is 0.2 to 0.4 nanometers greater than the second thickness.

Example 21 provides the IC structure of any one of the examples 1-20, where: a nanoribbon with a wider width (e.g., the first nanoribbon) is along the same ribbon path as two nanoribbons on either side of a dielectric wall (e.g., the second nanoribbon is adjacent to a dielectric wall on one side).

Example 22 provides the IC structure of example 21, where: a nanocomb transistor includes a channel region in the nanoribbons on either side of the dielectric wall.

Example 23 provides the IC structure of any one of the examples 1-20, where: a nanoribbon with a wider width (e.g., the first nanoribbon) is along the same ribbon path as two nanoribbons, and where the width of the two nanoribbons plus a distance between the two nanoribbons is about equal to the nanoribbon with the wider width.

Example 24 provides the IC structure of any one of examples 1-23, where: a first PMOS transistor has a channel region in the first nanoribbon, a second PMOS transistor has a channel region in the second nanoribbon, and where the IC structure includes a third nanoribbon parallel to and adjacent to the first and second nanoribbons, where an NMOS transistor has a channel region in the third nanoribbon.

Example 25 provides the IC structure o example 24, where: the third nanoribbon has about the same width as the second nanoribbon.

Example 26 provides an IC structure according to any one of examples 1-25, where the IC structure includes or is a part of a central processing unit.

Example 27 provides an IC structure according to any one of examples 1-26, where the IC structure includes or is a part of a memory device.

Example 28 provides an IC structure according to any one of examples 1-27, where the IC structure includes or is a part of a logic circuit.

Example 29 provides an IC structure according to any one of examples 1-28, where the IC structure includes or is a part of input/output circuitry.

Example 30 provides an IC structure according to any one of examples 1-29, where the IC structure includes or is a part of a field programmable gate array transceiver.

Example 31 provides an IC structure according to any one of examples 1-30, where the IC structure includes or is a part of a field programmable gate array logic.

Example 32 provides an IC structure according to any one of examples 1-31, where the IC structure includes or is a part of a power delivery circuitry.

Example 33 provides an IC package that includes an IC die including an IC structure according to any one of examples 1-32; and a further IC component, coupled to the IC die.

Example 34 provides an IC package according to example 33 where the further IC component includes a package substrate.

Example 35 provides an IC package according to example 34, where the further IC component includes an interposer.

Example 36 provides an IC package according to example 35, where the further IC component includes a further IC die.

Example 37 provides a computing device that includes a carrier substrate and an IC structure coupled to the carrier substrate, where the IC structure is an IC structure according to any one of examples 1-32, or the IC structure is included in the IC package according to any one of examples 33-36.

Example 38 provides a computing device according to example 37, where the computing device is a wearable or handheld computing device.

Example 39 provides a computing device according to examples 37 or 38, where the computing device further includes one or more communication chips.

Example 40 provides a computing device according to any one of examples 37-39, where the computing device further includes an antenna.

Example 41 provides a computing device according to any one of examples 37-40, where the carrier substrate is a motherboard.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first nanoribbon of a semiconductor material over a substrate, wherein:
the first nanoribbon has a first width, wherein the first width is a first dimension of the first nanoribbon in a plane substantially parallel with the substrate;
a first gate electrode material at least partially around the first nanoribbon;
a second nanoribbon of the semiconductor material over the substrate, wherein:
the second nanoribbon is coplanar with and substantially parallel with the first nanoribbon, and extending along a same line as the first nanoribbon,
the second nanoribbon has a second width, wherein the second width is a second dimension of the second nanoribbon in the plane, and
the first width is greater than the second width; and
a second gate electrode material at least partially around the second nanoribbon, wherein the second gate electrode material has a different material composition than the first gate electrode material.

2. The IC structure of claim 1, wherein:
the first gate electrode material comprises a metal and nitrogen, and
the second gate electrode material comprises the metal, nitrogen, and a P dipole material.

3. The IC structure of claim 1, wherein:
the first gate electrode material and the second gate electrode material comprise one or more of titanium and tungsten.

4. The IC structure of claim 3, wherein:
the second gate electrode material comprises aluminum.

5. The IC structure of claim 4, wherein:
aluminum is substantially absent from the first gate electrode material.

6. The IC structure of claim 1, further comprising:
a third nanoribbon adjacent to and substantially coplanar with the first nanoribbon and the second nanoribbon; and
a third gate electrode material at least partially around the third nanoribbon, wherein the third gate electrode material has a different material composition from the first gate electrode material and the second gate electrode material.

7. The IC structure of claim 6, wherein:
the third gate electrode material comprises titanium, aluminum, and carbon.

8. The IC structure of claim 1, wherein:
the first nanoribbon has a first thickness,
the second nanoribbon has a second thickness, and
the first thickness is smaller than the second thickness.

9. The IC structure of claim 1, wherein:
a gate dielectric material is thicker around the first nanoribbon than around the second nanoribbon.

10. An integrated circuit (IC) structure, comprising:
a first nanoribbon of a semiconductor material over a substrate, wherein:
the first nanoribbon has a first width and a first thickness,
the first width is a first dimension of the first nanoribbon in a first plane substantially parallel with the substrate, and
the first thickness is second dimension of the first nanoribbon in a second plane substantially orthogonal to the substrate; and
a second nanoribbon of the semiconductor material over the substrate, wherein:
the second nanoribbon is coplanar with and substantially parallel with the first nanoribbon, and extending along a same line as the first nanoribbon,
the second nanoribbon has a second width and a second thickness,
the second width is a third dimension of the second nanoribbon in the first plane,
the second thickness is a fourth dimension of the second nanoribbon in a third plane substantially orthogonal to the substrate,
the first width is greater than the second width, and
the first thickness is smaller than the second thickness.

11. The IC structure of claim 10, wherein:
the first thickness is about 10-30 percent smaller than the second thickness.

12. The IC structure of claim 10, wherein;
the first thickness is about 0.5 to 1.5 nanometers smaller than the second thickness.

13. The IC structure of claim 10, wherein:
the second thickness is in a range of about 4 to 6 nanometers.

14. The IC structure of claim 10, further comprising:
a first gate dielectric material at least partially around the first nanoribbon; and
a second gate dielectric material at least partially around the second nanoribbon, wherein:
the first gate dielectric material is thicker than the second gate dielectric material.

15. The IC structure of claim 14, wherein:
the first gate dielectric material has a same material composition as the second gate dielectric material.

16. The IC structure of claim 14, further comprising:
a first gate electrode material over the first gate dielectric material; and
a second gate electrode material over the second gate dielectric material, wherein:
the first gate electrode material has a different material composition from the second gate electrode material.

17. An integrated circuit (IC) structure, comprising:
a first nanoribbon of a semiconductor material over a substrate, wherein the first nanoribbon has a first width;
a first gate electrode material at least partially around the first nanoribbon;
a first gate dielectric material with a first thickness between the first nanoribbon and the first gate electrode material;
a second nanoribbon of the semiconductor material over the substrate, wherein:
the second nanoribbon is coplanar with and substantially parallel with the first nanoribbon, and extending along a same line as the first nanoribbon,
the second nanoribbon has a second width, and
the first width is greater than the second width;
a second gate electrode material at least partially around the second nanoribbon; and
a second gate dielectric material with a second thickness between the second nanoribbon and the second gate electrode material, wherein the first thickness is greater than the second thickness.

18. The IC structure of claim 17, wherein:
the second gate electrode material has a different material composition than the first gate electrode material.

19. The IC structure of claim 17, wherein:
the first thickness is about 25 to 35 percent greater than the second thickness.

20. The IC structure of claim 17, wherein:
the first thickness is 0.2 to 0.4 nanometers greater than the second thickness.
